(19) United States
(12) Patent Application Publication
(10) Pub. No.: US 2007/0285894 A1
(43) Pub. Date: Dec. 13, 2007

(54) Heat sink

(76) Inventors: Mehdi Hatamian, Coto De Caza, CA (US); Mehrtosh A. Ghalebi, Rancho Santa Margarita, CA (US)

Correspondence Address: STETINA BRUNDA GARRED & BRUCKER, 75 ENTERPRISE, SUITE 250, ALISO VIEJO, CA, 92656, US

(21) Appl. No.: 11/789,653

(22) Filed: Apr. 25, 2007

Related U.S. Application Data
(60) Provisional application No. 60/794,730, filed on Apr. 25, 2006.

(51) Int. Cl. H05K 7/20

(52) U.S. Cl. 361/710

(57) ABSTRACT

An improved heat sink that provides for the dissipation of heat via transfer to both air and liquids. The improved heat sink comprises an elongate structure defining a base for receiving heat from a heat-dissipating source. Extending from the base are a plurality of heat-dissipating structures, such as fins, that are operative to transfer heat to the surrounding air. The heat sink further comprises at least one channel extending therethrough, preferably intermediate the base and heat-dissipating structures extending therefrom, through which a liquid substance can pass to yet further absorb heat transferred thereabout via the base. The improved heat may further include structures disposed within the passageway for facilitating the flow of a fluid thereinto, preferably via capillary action.

### CROSS-REFERENCE TO RELATED APPLICATIONS

The present application claims priority to Provisional Patent Application Ser. No. 60/794,730, filed on Apr. 25, 2006, entitled HEAT SINK.

### STATEMENT RE: FEDERALLY SPONSORED RESEARCH/DEVELOPMENT

Not Applicable

### BACKGROUND

The present invention is directed to improved heat sinks, and more particularly, heat sinks that are operative to dissipate heat into both air and fluids circulating therethrough.

Heat sinks are well-known in the art. Generally, such structures are operative to facilitate the transfer of heat from a heat-dissipating source to an external environment, such as the air surrounding the heat sink and the like. Heat sinks are typically deployed where it is necessary to transfer heat or otherwise establish a temperature gradient where a measurable drop in temperature can be identified. Among the applications where heat sinks are deployed include the dissipation of heat generated from electronic componentry, such as microprocessors and the like, and peltier systems. Numerous other applications are also well-known in the art.

To achieve the desired transfer of heat, heat sinks are typically formed from materials such as aluminum that have good heat transfer properties. Heat sinks are further typically formed to have a plurality of structures, such as protuberances or fins, which extend in spaced relation to one another in order to maximize the surface area of the heat sink to thus facilitate the transfer of heat into the surrounding air.

Despite the general effectiveness of most heat sinks to dissipate heat into the surrounding air, heat sinks suffer from several disadvantages. Perhaps the most widely recognized is the fact that heat sinks rely upon the dissipation of heat into air, which is far less optimal than transferring heat to solid or liquid substances. In this regard, most heat sinks are typically must be used in combination with a fan in order to provide adequate circulation of air or to attain desired heat dissipation. While it is well-known that the transfer of heat is more greatly effectuated via the transfer of heat via solid or liquid substances, most heat sinks are not adapted to facilitate the transfer of heat to a liquid coolant. Such construction is typically far too complex or impractical for most applications, despite attaining optimal heat transfer.

There is therefore a substantial need in the art for a heat sink that is operative to facilitate the transfer of heat that can do so via a combination of air convection and/or heat transfer to a liquid coolant. There is further a need in the art for such a heat sink that is of simple construction, easy to manufacture, can be readily deployed in a variety of heat sink applications, and is greater at facilitating the transfer of heat than prior art heat sinks. There is further a need in the art for such a heat sink that, in addition to providing dual means by which heat can be transferred and dissipated (i.e., to either air or liquid), can further facilitate the flow of a liquid coolant passing therethrough.

### BRIEF SUMMARY

The present invention specifically addresses and alleviates the above-identified deficiencies in the art. In this regard, the present invention is directed to an improved heat sink that is operative to facilitate the transfer of heat by dual heat dissipation means, namely, convection whereby heat is dissipated into the air surrounding the heat sink and by the transfer of heat to a liquid passing through at least one channel formed within the heat sink. According to a preferred embodiment, the heat sink comprises an elongate member defining first and second ends. Extending along the length of the member is a base that is operative to be mounted against a heat-generating source, from which heat is transferred. Extending from the base are a plurality of heat dissipating structures, which preferably comprise fins, protuberances or other like structures, that are operative to maximize surface area so as to facilitate the dissipation of heat transferred to the base of the heat sink into the surrounding air per conventional heat sink design.

The heat sink further comprises at least one channel extending along the length of the heat sink and is preferably formed to extend between a portion of the base of the heat sink and plurality of heat dissipating structures (i.e., fins) extending therefrom. In certain embodiments, the heat sink will include two or more channels that will extend along the length of the heat sink in generally parallel relation to one another.

In a more highly refined embodiment, the channel or channels formed within the heat sink will be provided with one or more structures operative to facilitate the flow of a liquid therethrough. To that end, it is contemplated that such structures will comprise any type of structure, such as a wicking material, mesh, cylindrical body and the like that is operative to draw in fluid via capillary action. By utilizing such structures, particularly when the heat sink assumes a vertical position, fluid will at least be caused to enter a portion of the passageways formed within the heat sink without requiring any type of mechanical pumping mechanism, although the heat sink of the present invention could be adapted for use with such systems if desired.

### BRIEF DESCRIPTION OF THE DRAWINGS

These as well as other features of the present invention will become more apparent upon reference to the drawings.

FIG. 1 is a perspective view of an improved heat sink constructed in accordance to a preferred embodiment of the present invention.

FIG. 2 is a cross-sectional view taken along line 2-2 of FIG. 1.

### DETAILED DESCRIPTION

The detailed description set forth below is intended as a description of the presently preferred embodiment of the invention, and is not intended to represent the only form in which the present invention may be constructed or utilized. The description sets forth the functions and sequences of steps for constructing and operating the invention. It is to be understood, however, that the same or equivalent functions and sequences may be accomplished by different embodiments and that they are also intended to be encompassed within the scope of the invention.

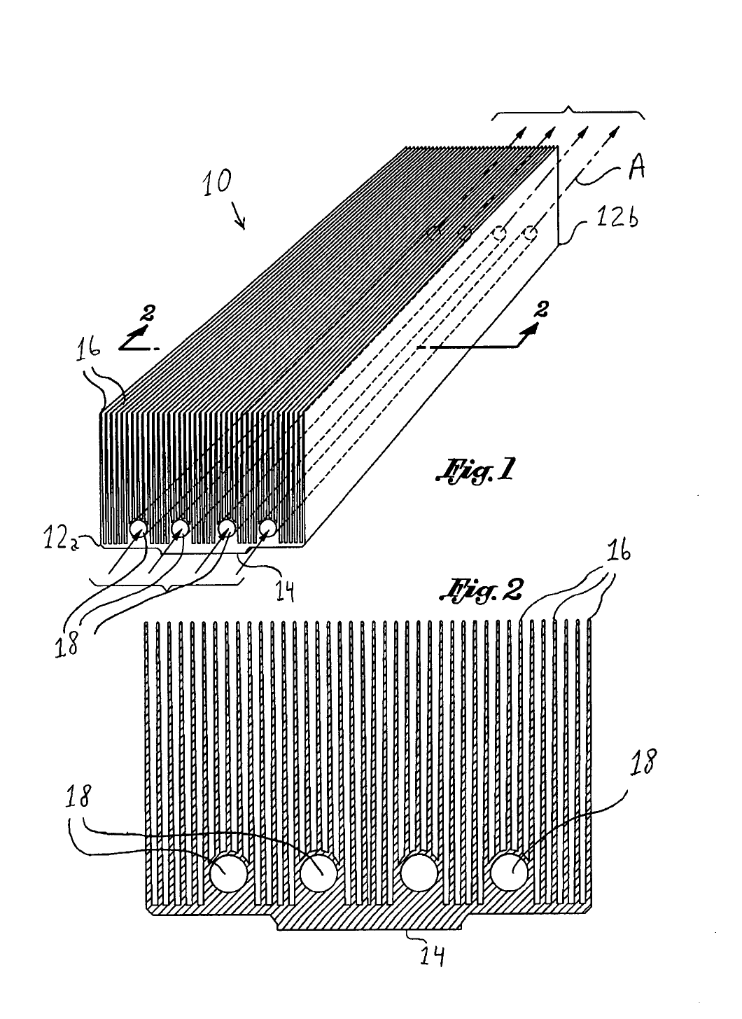

Referring now to the figures, and initially FIG. 1, there is shown an improved heat sink 10 as constructed in accordance with a preferred embodiment of the present invention. As illustrated, the heat sink 10 comprises an elongate member defining first and second ends 12a, 12b. Extending along the length of the improved heat sink 10 is a base 14, the latter being operative to be mounted upon a heat-generating source, such as an electronic component or otherwise incorporated as part of a heat transfer application, such as a peltier system and the like. Along these lines, it should be understood that the improved heat sink 10 of the present invention may be utilized for a wide variety of applications as will be readily understood by those skilled in the art.

Extending from the base 14 are a plurality of heat-dissipating structures, such as 16 as shown. As will be well-understood by those skilled in the art, such structures, such as 16, are preferably designed to maximize surface area so as to increase the ability of the heat sink 10 to dissipate the heat transferred thereto into the surrounding air, as per conventional heat sink construction. As will further be readily understood, although depicted as fins 16, the improved heat sink 10 of the present invention may be configured such that any of a variety of structures may be formed to extend from the base 14 so as to maximize surface area. For example, it should be understood that structures such as columns, protuberances, corrugated structures and the like could be readily integrated as heat-dissipating structures.

In addition to being operative to dissipate heat into the surrounding air via heat-dissipating structures 16, the improved heat sink 10 of the present invention will further be operative to facilitate the transfer of heat to a liquid substance as well. To that end, the improved sink 10 will preferably be provided with at least one channel 18 that will extend along the length of the improved heat sink 10. As illustrated in FIGS. 1 and 2, the improved heat sink 10 is shown with four channels 18 that are formed in generally parallel relation to one another intermediate base 14 and rows of the heat-dissipating fin structures 16.

In order to accommodate the flow of the liquid material, the passageways 18 are preferably formed to have a cylindrical shape, although other shapes and configurations can be readily incorporated and substituted therefore. Although not shown, in certain preferred embodiments of the present invention, the improved heat sink 10 will include structures disposed within the channels 18 that are operative to facilitate the flow of fluid therethrough. In particular, it is contemplated that any type of wicking material, mesh and/or cylindrical-type structures may be incorporated therein that are operative to draw fluid therein via capillary action when the improved heat sink 10 assumes a vertical orientation. As will be readily appreciated by those skilled in the art, to provide such structures will enable fluid to be drawn in to a dedicated channel 18 without the need for any type of mechanical pumping action or the like. It should be understood, however, the improved heat sink 10 of the present invention can be utilized in connection with pumping mechanisms to the extent it is desired for a given application to have a continuous flow of fluid pass through one of more channels 18, as indicated by the direction “A” as shown in FIG. 1. Along these lines, it will be readily appreciated by those skilled in the art that the continuous flow of fluid through one or more of the channels 18 will yet further be operative to facilitate the transfer of heat away from base 14 and to any fluid passing through channels 18, as will be readily understood with reference to FIG. 2.

The improved heat sink can be readily fabricated according to known techniques and from materials that are ideally suited for facilitating the transfer of heat. For example, it will be readily appreciated that the improved heat sink 10 can be readily formed from aluminum extrusion processes, and the like. Moreover, it is expressly contemplated that while materials such as aluminum and other alloys having high heat-transfer properties will be ideally suited for the practices of the present invention, other materials suited for similar applications will be readily understood and available to those skilled in the art. It will also be readily understood that the dimensions of base 14, heat-dissipating structures 16 and channels 18 can be varied to accommodate a particular application.

Additional modifications and improvements of the present invention may also be apparent to those of ordinary skill in the art. Thus, the particular combination of parts and steps described and illustrated herein is intended to represent only certain embodiments of the present invention, and is not intended to serve as limitations of alternative devices and methods within the spirit and scope of the invention.

What is claimed is:

1. An improved heat sink comprising:
a. an elongate member having first and second ends and defining a length, said member having a base extending along the length thereof and operative to be coupled with a heat-generating source;
b. a plurality of heat-dissipating structures extending from said base and operative to dissipate heat received from said base into the surrounding air; and
c. at least one channel extending through the length of said member, said channel being formed intermediate a portion of said base and said plurality of heat-dissipating structures extending therefrom.

2. The improved heat sink of claim 1 wherein said improved heat sink comprises at least two channels extending therethrough, said channels extending along the length of said member in generally parallel relation to one another.

3. The improved heat sink of claim 1 wherein said heat sink is fabricated from aluminum.

4. The improved heat sink of claim 1 wherein said at least one channel has a structure formed therein for drawing fluid into said channel via capillary action.

5. The improved heat sink of claim 4 wherein said structure is selected from the group consisting of a wicking material, a mesh and a cylindrical body.

6. The improved heat sink of claim 1 wherein said base is operatively interconnectable with a heat-generating component.

7. The improved heat sink of claim 1 wherein said base is operative to be integrated within a peltier system.
